(19) United States
(12) Patent Application Publication
(10) Pub. No.: US 2026/0181927 A1
(43) Pub. Date: Jun. 25, 2026

(54) LAYER-SUBTRACTIVE SEMICONDUCTOR PROCESSING

(71) Applicant: TEXAS INSTRUMENTS INCORPORATED, Dallas, TX (US)

(72) Inventors: Joshua Lane, Sherman, TX (US); Christopher Thomas Reese, McKinney, TX (US)

(21) Appl. No.: 18/989,992

(22) Filed: Dec. 20, 2024

(51) Int. Cl. H10D 10/01; H10D 10/40

(52) U.S. Cl. CPC H10D 10/051; H10D 10/421

(57) ABSTRACT

The present disclosure generally relates to layer-subtractive semiconductor processing, such as for a bipolar junction transistor (BJT). In an example, a semiconductor layer stack is formed over a semiconductor substrate. The semiconductor layer stack includes a first semiconductor layer over the semiconductor substrate, a second semiconductor layer over the first semiconductor layer, and a third semiconductor layer over the second semiconductor layer. The first and third semiconductor layers have a same conductivity type, and the second semiconductor layer has a conductivity type opposite from the conductivity type of the first and third semiconductor layers. The semiconductor layer stack is patterned into a first mesa. The first mesa forms an emitter of a BJT. The semiconductor layer stack is patterned into a second mesa. The second mesa extends laterally from the first mesa. The first mesa is over the second mesa. The second mesa forms a base of the BJT.

### BACKGROUND

Semiconductor processing to fabricate integrated circuits (IC) may include many processing steps. An IC may include different disparate devices that may necessitate unique processing for each type of device. Integrating the processing for these devices into a flow may cause many processing steps to be implemented. The costs to perform these processing steps to a completed IC die can be large.

### SUMMARY

This summary is provided to introduce a brief selection of disclosed concepts in a simplified form that are further described below in the detailed description including the drawings provided. Various disclosed devices and methods may be beneficially applied in the context of semiconductor processing for manufacturing an integrated circuit (IC). Some examples described herein may be applied to manufacturing an IC that includes one or more bipolar junction transistors (BJTs). While such examples may be expected to achieve a reduced number of processing steps, reduced manufacturing time and costs, and/or improved isolation and leakage characteristics, no particular result is a requirement unless explicitly recited in a particular claim.

An example described herein is a method of manufacturing an IC. A semiconductor layer stack is formed over a semiconductor substrate. The semiconductor layer stack includes a first semiconductor layer over the semiconductor substrate, a second semiconductor layer over the first semiconductor layer, and a third semiconductor layer over the second semiconductor layer. The first semiconductor layer and the third semiconductor layer have a same conductivity type, and the second semiconductor layer has a conductivity type opposite from the conductivity type of the first semiconductor layer and the third semiconductor layer. The semiconductor layer stack is patterned into a first mesa in a region. The first mesa forms an emitter of a BJT. The semiconductor layer stack is patterned into a second mesa in the region. The second mesa extends laterally from the first mesa. The first mesa is over the second mesa. The second mesa forms a base of the BJT.

Another example described herein is a method of manufacturing an IC. A first epitaxial layer is formed over a semiconductor substrate. The first epitaxial layer has a first conductivity type. A second epitaxial layer is formed over the first epitaxial layer. The second epitaxial layer has a second conductivity type opposite from the first conductivity type. A third epitaxial layer is formed over the second epitaxial layer. The third epitaxial layer has the first conductivity type. The third epitaxial layer is etched to form an emitter layer of a BJT in a region. The second epitaxial layer is etched to form a base layer of the BJT in the region. The emitter layer is over the base layer. The base layer extends laterally from the emitter layer.

A further example described herein is an IC. The IC includes a semiconductor substrate, a BJT, and a conformal dielectric layer. The BJT includes a semiconductor layer stack over the semiconductor substrate. The semiconductor layer stack includes a base semiconductor layer over the semiconductor substrate and an emitter semiconductor layer over the base semiconductor layer. The base semiconductor layer extends laterally from the emitter semiconductor layer. The conformal dielectric layer is on the semiconductor layer stack and in a recess in the semiconductor substrate.

Another example described herein is a method of manufacturing an IC. A BJT is formed. Forming the BJT includes forming a semiconductor layer stack over a semiconductor substrate. Forming the semiconductor layer stack includes forming a base semiconductor layer over the semiconductor substrate and forming an emitter semiconductor layer over the base semiconductor layer. The base semiconductor layer extends laterally from the emitter semiconductor layer. A conformal dielectric layer is formed on the semiconductor layer stack and in a recess in the semiconductor substrate.

The foregoing summary outlines rather broadly various features of examples of the present disclosure in order that the following detailed description may be better understood. Additional features and advantages of such examples will be described hereinafter. The described examples may be readily utilized as a basis for modifying or designing other examples that are within the scope of the disclosure.

### BRIEF DESCRIPTION OF THE DRAWINGS

So that the manner in which the above recited features may be understood in detail, reference is made to the following detailed description taken in conjunction with the accompanying drawings.

FIGS. 1 through 8 are cross-sectional views of an integrated circuit (IC) during respective stages of manufacturing according to some examples.

The drawings, and accompanying detailed description, are provided for understanding of features of various examples and do not limit the scope of the appended claims. The examples illustrated in the drawings and described in the accompanying detailed description may be readily utilized as a basis for modifying or designing other examples that are within the scope of the disclosure. Identical reference numerals may be used, where possible, to designate identical elements that are common among drawings. The figures are drawn to clearly illustrate the relevant elements or features and are not necessarily drawn to scale.

### DETAILED DESCRIPTION

Various features are described hereinafter with reference to the figures. An illustrated example may not have all the aspects or advantages shown. An aspect or an advantage described in conjunction with a particular example is not necessarily limited to that example and may be practiced in any other examples even if not so illustrated or if not so explicitly described. Further, methods described herein may be described in a particular order of operations, but other methods according to other examples may be implemented in various other orders (e.g., including different serial or parallel performance of various operations) with more or fewer operations. In the following discussion, doping levels may be described in quantitative and/or qualitative terms, wherein a doping level less than 1×10¹⁶ cm⁻³ is lightly doped, a doping level between 1×10¹⁶ cm⁻³ and 1×10¹⁸ cm³ is moderately doped, a doping level between 1×10¹⁸ cm⁻³ and 1×10²⁰ cm³ is heavily doped, and a doping level above 1×10²⁰ cm⁻³ is very heavily doped. A doping level at the boundaries of these ranges may be referred to qualitatively by either term referring to the higher or lower range.

The present disclosure relates generally, but not exclusively, to layer-subtractive semiconductor processing, such as for a bipolar junction transistor (BJT). In some examples, a semiconductor layer stack that includes multiple semiconductor layers is formed over a semiconductor substrate. The semiconductor layer stack is patterned into a first mesa and a second mesa. The first mesa is over the second mesa, and the second mesa extends laterally from the first mesa. The first and second mesas form respective components of a BJT. Examples described herein may avoid some processing steps and may implement a process flow that includes fewer processing steps than some baseline methods, which may reduce manufacturing time and costs. Additionally, improved isolation and leakage characteristics may be achieved in devices formed using the semiconductor processing described herein. Other benefits or advantages may be achieved by various examples.

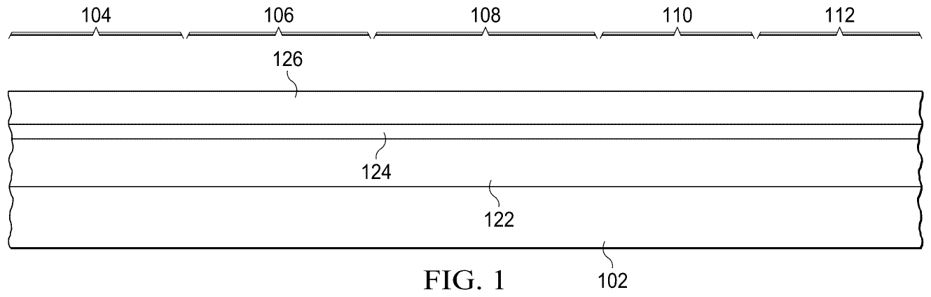

FIGS. 1 through 8 are cross-sectional views of an integrated circuit (IC) during respective stages of manufacturing according to some examples. Referring to FIG. 1, a semiconductor substrate 102 is provided. The semiconductor substrate 102 may be or include a bulk wafer, a semiconductor-on-insulator (SOI) substrate, or the like. The semiconductor substrate 102 may be or include any semiconductor material, such as silicon (Si), silicon germanium (SiGe), gallium arsenide (GaAs), the like, or a combination thereof, and may include a bulk material (e.g., bulk silicon). In some examples, the semiconductor substrate 102 may be p-doped with a p-type dopant (e.g., boron (B)) at a concentration in a range from about 1×10¹⁴ cm⁻³ to about 5×10¹⁵ cm⁻³, e.g., lightly doped. The semiconductor substrate 102 includes a first device region 104, a second device region 106, a third device region 108, a fourth device region 110, and a fifth device region 112. Respective devices are formed in the device regions 104-112 as illustrated subsequently.

A semiconductor layer stack is formed over (e.g., on) the semiconductor substrate 102. In the illustrated example, the semiconductor layer stack is a tri-layer stack. The semiconductor layer stack includes a first semiconductor layer 122 over the semiconductor substrate 102, a second semiconductor layer 124 over the first semiconductor layer 122, and a third semiconductor layer 126 over the second semiconductor layer 124. In some examples, the semiconductor layers 122-126 are respective epitaxial semiconductor layers. In some examples, each of the semiconductor layers 122-126 are or include a same semiconductor material as the semiconductor material of the semiconductor substrate 102 over which the semiconductor layer stack is formed. For example, each of the semiconductor layers 122-126 may be predominantly silicon, possibly including dopants as otherwise described. The semiconductor layers 122-126 may include different semiconductor material(s) in other examples.

The first semiconductor layer 122 and the third semiconductor layer 126 have a same conductivity type (e.g., are doped with a same dopant type). The second semiconductor layer 124 has a conductivity type (e.g., is doped with a dopant type) opposite from the conductivity type of the first semiconductor layer 122 and the third semiconductor layer 126. For example, the first semiconductor layer 122 and the third semiconductor layer 126 are doped with an n-type dopant (e.g., phosphorus (P) or arsenic (As)), and the second semiconductor layer 124 is doped with a p-type dopant (e.g., boron (B)). In some examples, the first semiconductor layer 122 is doped with an n-type dopant at a concentration in a range from about 1×10¹⁵ cm⁻³ to about 5×10¹⁸ cm⁻³, e.g., lightly to heavily doped; the second semiconductor layer 124 is doped with a p-type dopant at a concentration in a range from about 1×10¹³ cm⁻³ to about 5×10¹⁵ cm⁻³, e.g., lightly doped; and the third semiconductor layer 126 is doped with an n-type dopant at a concentration in a range from about 1×10¹⁵ cm⁻³ to about 1×10²⁰ cm⁻³, e.g., lightly to heavily doped. Other dopant concentrations may be implemented, and conductivity types of the semiconductor layers 122-126 may differ (e.g., be opposite from what is described in specific examples).

In some examples, the first semiconductor layer 122 may have a thickness that is greater than a thickness of the second semiconductor layer 124 and a thickness of the third semiconductor layer 126, and the thickness of the third semiconductor layer 126 may be greater than the thickness of the second semiconductor layer 124. A thickness of a layer generally is in a direction orthogonal to a surface on which that layer is formed. In some examples, a thickness of the first semiconductor layer 122 is in a range from 8 μm to 10 μm (e.g., 9 μm); a thickness of the second semiconductor layer 124 is in a range from 0.5 μm to 2 μm (e.g., 1 μm); and a thickness of the third semiconductor layer 126 is in a range from 1 μm to 3 μm (e.g., 2 μm). Other thicknesses of the semiconductor layers 122-126 may be implemented.

The semiconductor layers 122-126 may be formed using an epitaxial growth process, such as low pressure chemical vapor deposition (LPCVD), reduced pressure chemical vapor deposition (RPCVD), metal organic chemical vapor deposition (MOCVD), or the like. The semiconductor layers 122-126 may be doped by in situ doping during the epitaxial growth with dopant types and concentrations as described above.

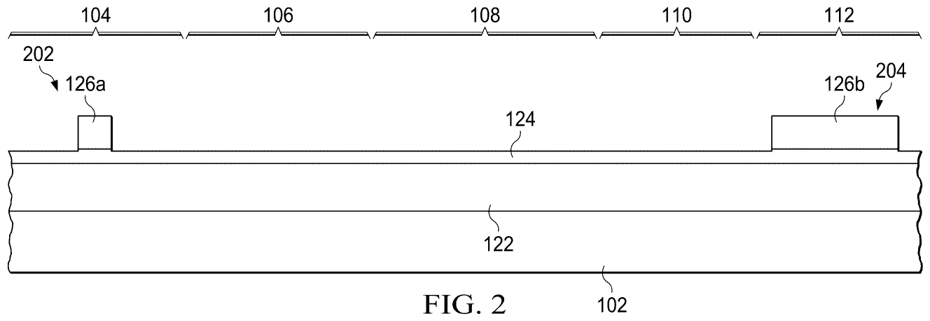

Referring to FIG. 2, the semiconductor layer stack is patterned to form a first device first mesa 202 in the first device region 104 and a fifth device mesa 204 in the fifth device region 112. The patterning, as illustrated in FIG. 2, removes (e.g., etches through) the third semiconductor layer 126 outside of the first device first mesa 202 and the fifth device mesa 204 and may further remove an upper portion of the second semiconductor layer 124 in areas where the third semiconductor layer 126 is removed. In the illustrated example, the first device first mesa 202 includes a first patterned third semiconductor layer 126a patterned from the third semiconductor layer 126, and the fifth device mesa 204 includes a second patterned third semiconductor layer 126b patterned from the third semiconductor layer 126. The first device first mesa 202 and fifth device mesa 204 may further include an upper portion of the second semiconductor layer 124 underlying the patterned third semiconductor layers 126a, 126b, respectively. The semiconductor layer stack may be patterned using appropriate photolithography and etch (e.g., reactive ion etch (RIE)) processes.

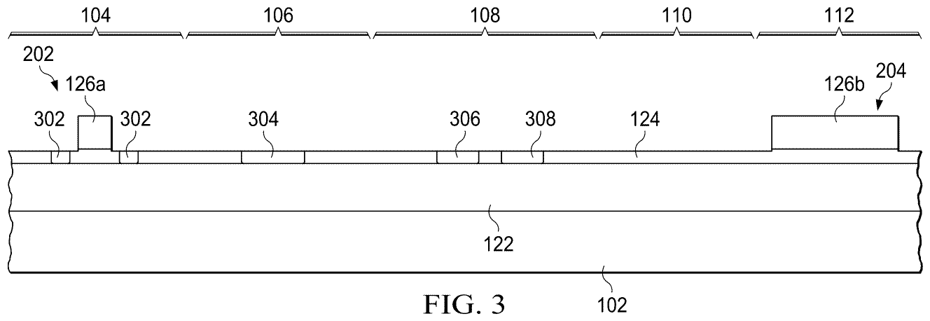

Referring to FIG. 3, base contact regions 302 in the first device region 104, an emitter region 304 in the second device region 106, and a collector region 306 and an emitter region 308 in the third device region 108 are formed in the semiconductor layer stack. The base contact regions 302 are in the second semiconductor layer 124 on opposing sides of the first device first mesa 202 (e.g., the first patterned third semiconductor layer 126a). Similarly, the emitter region 304, collector region 306, and emitter region 308 are in the second semiconductor layer 124. The regions 302-308 have a conductivity type that is the same as the conductivity type of the second semiconductor layer 124 and opposite from the conductivity type of the first semiconductor layer 122. In some examples, the regions 302-308 are doped with a p-type dopant at a concentration greater than a concentration of the p-type dopant of the second semiconductor layer 124. For example, the base contact regions 302 are doped with a p-type dopant at a concentration in a range from about 1×10¹⁸ cm⁻³ to about 1×10²⁰ cm⁻³, e.g., heavily doped; the emitter region 304 is doped with a p-type dopant at a concentration in a range from about 1×10¹⁸ cm⁻³ to about 1×10²⁰ cm⁻³, e.g., heavily doped; the collector region 306 is doped with a p-type dopant at a concentration in a range from about 1×10¹⁶ cm⁻³ to about 1×10¹⁸ cm⁻³, e.g., moderately doped; and the emitter region 308 is doped with a p-type dopant at a concentration in a range from about 1×10¹⁸ cm⁻³ to about 1×10²⁰ cm⁻³, e.g., heavily doped. The regions 302-308 may be formed using photolithography and implantation processes. In some examples, the regions 302-308 may be formed using a same implantation process, or the base contact regions 302 may be formed using an implantation process different from an implantation process that forms the regions 304-308. A diffusion process may be performed following the implantation to diffuse dopants in the semiconductor layer stack. The diffusion process may be a thermal process, such as an anneal (e.g., a rapid thermal anneal (RTA)) or the like.

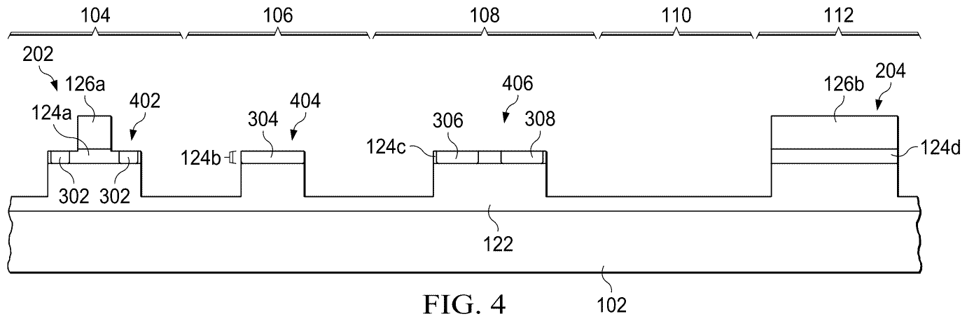

Referring to FIG. 4, the semiconductor layer stack is patterned to form a first device second mesa 402 in the first device region 104, a second device mesa 404 in the second device region 106, and a third device mesa 406 in the third device region 108 and to extend the fifth device mesa 204 into the semiconductor layer stack. The patterning, as illustrated in FIG. 4, removes (e.g., etches through) the second semiconductor layer 124 outside of the first device second mesa 402, second device mesa 404, third device mesa 406, and fifth device mesa 204 and may further remove an upper portion of the first semiconductor layer 122 in areas where the second semiconductor layer 124 is removed. In the illustrated example, the first device second mesa 402 includes a first patterned second semiconductor layer 124a patterned from the second semiconductor layer 124; the second device mesa 404 includes a second patterned second semiconductor layer 124b patterned from the second semiconductor layer 124; the third device mesa 406 includes a third patterned second semiconductor layer 124c patterned from the second semiconductor layer 124; and the fifth device mesa 204 further includes a fourth patterned second semiconductor layer 124d patterned from the second semiconductor layer 124. The first device second mesa 402, second device mesa 404, third device mesa 406, and fifth device mesa 204 may further include an upper portion of the first semiconductor layer 122 underlying the patterned second semiconductor layers 124a, 124b, 124c, 124d, respectively.

The first device second mesa 402 is under the first device first mesa 202 and extends laterally from the first device first mesa 202. The first device second mesa 402 includes the base contact regions 302 on laterally opposing sides of the first device first mesa 202 (e.g., the first patterned third semiconductor layer 126a). The second device mesa 404 includes the emitter region 304. The second device mesa 404 may have a lateral dimension that is smaller than the emitter region 304 as formed in FIG. 3, and hence, the patterning of the second device mesa 404 may remove some of the emitter region 304 that was formed in FIG. 3. The third device mesa 406 includes the collector region 306 and emitter region 308. In some examples, further extending the fifth device mesa 204 through the second semiconductor layer 124 may form another mesa such that the fourth patterned second semiconductor layer 124d extends laterally from the fifth device mesa 204 (e.g., the second patterned third semiconductor layer 126b), such as by misalignment of photolithography masks. The semiconductor layer stack may be patterned using appropriate photolithography and etch (e.g., RIE) processes.

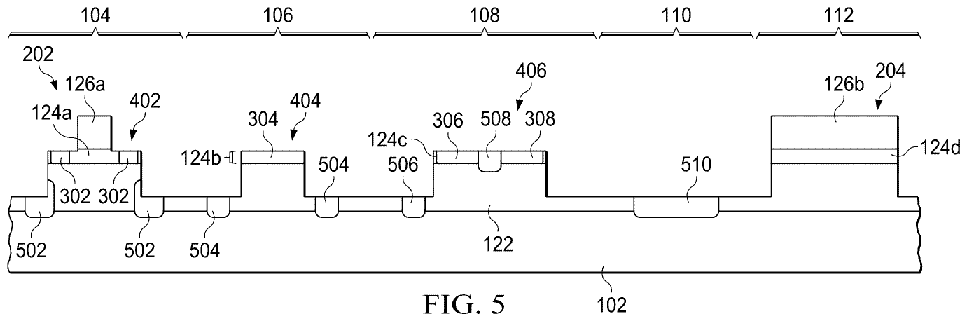

Referring to FIG. 5, collector contact regions 502 in the first device region 104, base contact regions 504 in the second device region 106, a base contact region 506 and a base region 508 in the third device region 108, and a Zener region 510 in the fourth device region 110 are formed in the semiconductor layer stack. The collector contact regions 502 are in the first semiconductor layer 122 and extend into the semiconductor substrate 102 on opposing sides of the first device second mesa 402 (e.g., the first patterned second semiconductor layer 124a). The collector contact regions 502 may further include respective portions thereof in the first semiconductor layer 122 at respective sidewalls of the first semiconductor layer 122 that form a portion of the first device second mesa 402. The base contact regions 504 are in the first semiconductor layer 122 and extend into the semiconductor substrate 102 on opposing sides of the second device mesa 404 (e.g., the second patterned second semiconductor layer 124b). The base contact region 506 is in the first semiconductor layer 122 and extends into the first semiconductor layer 122 laterally proximate to the third device mesa 406 (e.g., the third patterned second semiconductor layer 124c). The base region 508 is in the third patterned second semiconductor layer 124c and extends into the first semiconductor layer 122 laterally between the collector region 306 and the emitter region 308. In some examples, the base region 508 may be omitted. The Zener region 510 is in the first semiconductor layer 122 and extends into the semiconductor substrate 102.

The regions 502-510 have a conductivity type that is the same as the conductivity type of the first semiconductor layer 122 and opposite from the conductivity type of the second semiconductor layer 124 and semiconductor substrate 102. In some examples, the regions 502-510 are doped with an n-type dopant at a concentration greater than a concentration of the n-type dopant of the first semiconductor layer 122. For example, the collector contact regions 502 are doped with an n-type dopant at a concentration in a range from about 1×10¹⁸ cm⁻³ to about 5×10²⁰ cm⁻³, e.g., heavily to very heavily doped; the base contact regions 504 are doped with an n-type dopant at a concentration in a range from about 1×10¹⁸ cm⁻³ to about 5×10²⁰ cm⁻³, e.g., heavily to very heavily doped; the base contact region 506 is doped with an n-type dopant at a concentration in a range from about 1×10¹⁸ cm⁻³ to about 5×10²⁰ cm⁻³, e.g., heavily to very heavily doped; the base region 508 is doped with an n-type dopant at a concentration in a range from about 1×10¹⁶ cm⁻³ to about 1×10¹⁸ cm⁻³, e.g., moderately doped; and the Zener region 510 is doped with an n-type dopant at a concentration in a range from about 1×10¹⁸ cm⁻³ to about 5×10²⁰ cm⁻³, e.g., heavily to very heavily doped. The regions 502-510 may be formed using photolithography and implantation processes, which may include a tilt implantation. A diffusion process may be performed following the implantation to diffuse dopants in the semiconductor layer stack and/or semiconductor substrate 102. The diffusion process may be a thermal process, such as an anneal (e.g., an RTA) or the like.

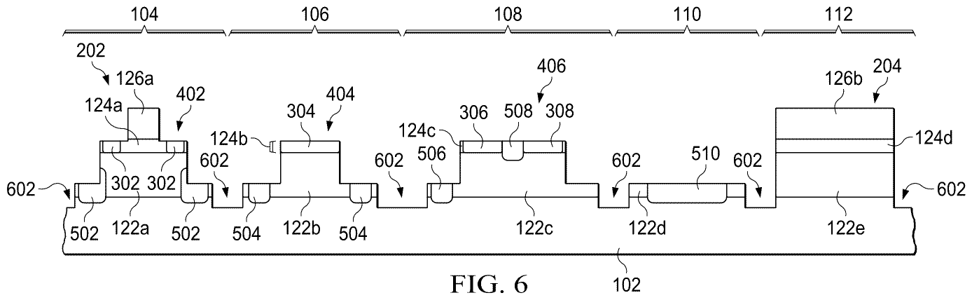

Referring to FIG. 6, recesses 602 are formed in the semiconductor substrate 102. The recesses 602, as illustrated, are also formed through any remaining layer of the semiconductor layer stack, such as the first semiconductor layer 122, where the recesses 602 are formed. Forming the recesses 602, in the illustrated example, forms a first patterned first semiconductor layer 122a (which may form a mesa) in the first device region 104 patterned from the first semiconductor layer 122, a second patterned first semiconductor layer 122b (which may form a mesa) in the second device region 106 patterned from the first semiconductor layer 122, a third patterned first semiconductor layer 122c (which may form a mesa) in the third device region 108 patterned from the first semiconductor layer 122, a fourth patterned first semiconductor layer 122d (which may form a mesa) in the fourth device region 110 patterned from the first semiconductor layer 122, and a fifth patterned first semiconductor layer 122e (which may extend the fifth device mesa 204) in the fifth device region 112 patterned from the first semiconductor layer 122. The first patterned first semiconductor layer 122a includes at least respective portions of the collector contact regions 502. The second patterned first semiconductor layer 122b includes at least respective portions of the base contact regions 504. The third patterned first semiconductor layer 122c includes at least a portion of the base contact region 506. The fourth patterned first semiconductor layer 122d includes at least a portion of the Zener region 510. The recesses 602 are formed at peripheries of the device regions 104-112 and laterally between devices that are formed. The recesses 602 may be formed using appropriate photolithography and etch (e.g., RIE) processes.

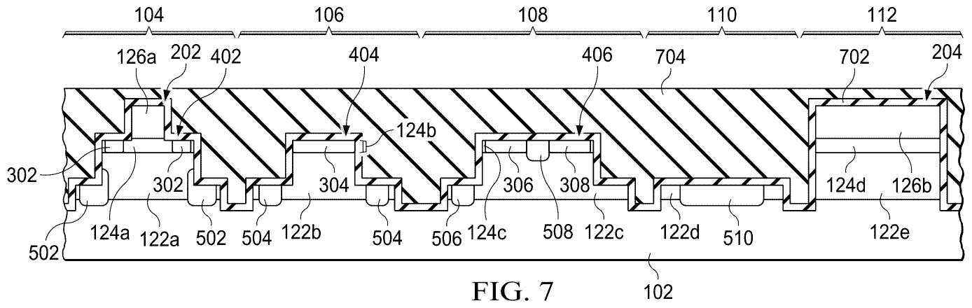

Referring to FIG. 7, a first dielectric layer 702 is formed over (e.g. on) the patterned semiconductor layer stack and in the recesses 602 in the semiconductor substrate 102, and a second dielectric layer 704 is formed over the first dielectric layer 702. The first dielectric layer 702 is formed conformally over the patterned semiconductor layer stack and may be referred to as a component conformal dielectric layer or a device conformal dielectric layer. In some examples, the first dielectric layer 702 is formed by an oxidation process, such as in situ steam generation (ISSG) oxidation or the like, and in other examples, the first dielectric layer 702 is formed by a deposition process, such as a chemical vapor deposition (CVD), atomic layer deposition (ALD), or the like. In some examples, the first dielectric layer 702 may be or include an oxide, such as silicon oxide when the semiconductor layer stack is or includes silicon and the first dielectric layer 702 is formed by oxidation. In some examples, the first dielectric layer 702 may be or include a nitride or other dielectric material.

The second dielectric layer 704 may be a pre-metal dielectric (PMD), an interlayer dielectric (ILD), an intermetal dielectric (IMD), or the like. The second dielectric layer 704 may be or include silicon oxide (such as phosphosilicate glass (PSG) or a tetraethyl orthosilicate (TEOS) oxide), the like, or a combination thereof. In some examples, the second dielectric layer 704 may be deposited by CVD, such as plasma enhanced CVD (PECVD). The second dielectric layer 704 may be planarized, such as by a chemical mechanical polish (CMP).

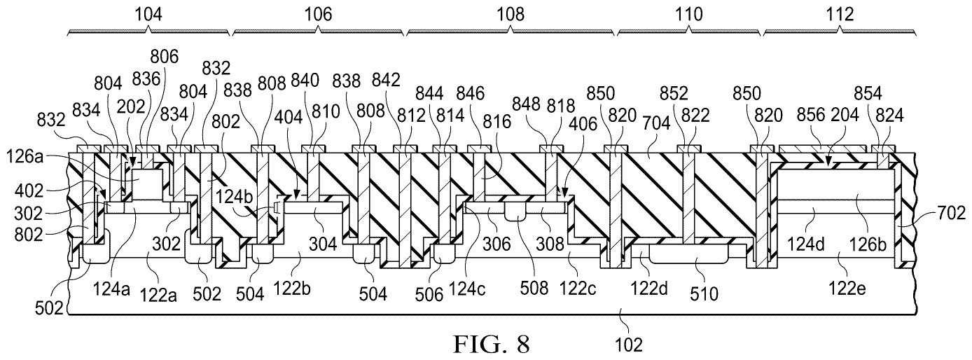

Referring to FIG. 8, metal contacts 802, 804, 806, 808, 810, 812, 814, 816, 818, 820, 822, 824 are formed through the dielectric layers 702, 704, and metal lines 832, 834, 836, 838, 840, 842, 844, 846, 848, 850, 852, 854 and a metal plate 856 are formed over (e.g., on) the second dielectric layer 704. The metal contacts 802 contact the collector contact regions 502. The metal contacts 804 contact the base contact regions 302. The metal contact 806 contacts the first patterned third semiconductor layer 126a. Hence, the metal contacts 802-806 are metal contacts for and electrically connected to the semiconductor device (e.g., BJT) in the first device region 104. The metal contacts 808 contact the base contact regions 504. The metal contact 810 contacts the emitter region 304. The metal contact 812 contacts the semiconductor substrate 102. Hence, the metal contacts 808-812 are metal contacts for and electrically connected to the semiconductor device (e.g., BJT) in the second device region 106. The metal contact 814 contacts the base contact region 506. The metal contact 816 contacts the collector region 306. The metal contact 818 contacts the emitter region 308. Hence, the metal contacts 814-818 are metal contacts for and electrically connected to the semiconductor device (e.g., BJT) in the third device region 108. The metal contacts 820 contact the semiconductor substrate 102. The metal contact 822 contacts the Zener region 510. Hence, the metal contacts 820, 822 are metal contacts for and electrically connected to the semiconductor device (e.g., diode) in the fourth device region 110. The metal contact 824 contacts the second patterned third semiconductor layer 126b. Hence, the metal contact 824 is a metal contact for and electrically connected to the semiconductor device (e.g., capacitor) in the fifth device region 112. The metal lines 832-854 are over and contact the metal contacts 802-824, respectively. The metal plate 856 is over the second patterned third semiconductor layer 126b with the first dielectric layer 702 and second dielectric layer 704 disposed between the metal plate 856 and the second patterned third semiconductor layer 126b.

The metal contacts 802-824 may each include one or more barrier and/or adhesion layers (e.g., titanium nitride (TiN), tantalum nitride (TaN), the like, or a combination thereof) conformally in a respective opening through the dielectric layers 702, 704, and a fill metal (e.g., tungsten (W), copper (Cu), aluminum (Al), the like, or a combination thereof) over and/or on the barrier and/or adhesion layer(s). Similarly, the metal lines 832-854 and metal plate 856 may each include one or more barrier and/or adhesion layers (e.g., titanium nitride (TiN), tantalum nitride (TaN), the like, or a combination thereof) over the second dielectric layer 704, and a fill metal (e.g., tungsten (W), copper (Cu), aluminum (Al), the like, or a combination thereof) over and/or on the barrier and/or adhesion layer(s). Contact openings may be formed using appropriate photolithography and etch (e.g., RIE) processes. Metal(s) for the metal contacts 802-824, metal lines 832-854, and metal plate 856 may be deposited, such as by CVD, physical vapor deposition (PVD), or the like, in the contact openings and over the second dielectric layer 704. Metal(s) over the second dielectric layer 704 may then be patterned into the metal lines 832-854 and metal plate 856 using appropriate photolithography and etch (e.g., RIE) processes.

The first device region 104 includes a first bipolar junction transistor (BJT), which may be an NPN BJT. Further, the NPN BJT may be a vertical NPN BJT. The first BJT in the first device region 104 includes the first patterned third semiconductor layer 126a as an emitter, the first patterned second semiconductor layer 124a (with base contact regions 302) as a base, and the first patterned first semiconductor layer 122a (with collector contact regions 502) as a collector. The first dielectric layer 702 is conformal to the first patterned first semiconductor layer 122a, first patterned second semiconductor layer 124a, and first patterned third semiconductor layer 126a. For example, the first dielectric layer 702 is on sidewalls and upper surfaces of the first patterned first semiconductor layer 122a, first patterned second semiconductor layer 124a, and first patterned third semiconductor layer 126a. The first dielectric layer 702 is further on sidewalls and bottom surfaces that define the recesses 602 in the semiconductor substrate 102 that are at a periphery of the first BJT.

The second device region 106 includes a second BJT, which may be a PNP BJT. Further, the PNP BJT may be a vertical PNP BJT. The second BJT in the second device region 106 includes the second patterned second semiconductor layer 124b with the emitter region 304 as an emitter, the second patterned first semiconductor layer 122b (with base contact regions 504) as a base, and a portion (e.g., a p-doped portion or region) of the semiconductor substrate 102 as a collector (e.g., electrically contacted through metal contact 812). The first dielectric layer 702 is conformal to the second patterned first semiconductor layer 122b and second patterned second semiconductor layer 124b. For example, the first dielectric layer 702 is on sidewalls and upper surfaces of the second patterned first semiconductor layer 122b and second patterned second semiconductor layer 124b. The first dielectric layer 702 is further on sidewalls and bottom surfaces that define the recesses 602 in the semiconductor substrate 102 that are at a periphery of the second BJT.

The third device region 108 includes a third BJT, which may be a PNP BJT. Further, the PNP BJT may be a lateral PNP BJT. The third BJT in the third device region 108 includes the emitter region 308 as an emitter, the base region 508 as a base, and the collector region 306 as a collector. The first dielectric layer 702 is conformal to the third patterned first semiconductor layer 122c and third patterned second semiconductor layer 124c. For example, the first dielectric layer 702 is on sidewalls and upper surfaces of the third patterned first semiconductor layer 122c and third patterned second semiconductor layer 124c. The first dielectric layer 702 is further on sidewalls and bottom surfaces that define the recesses 602 in the semiconductor substrate 102 that are at a periphery of the third BJT.

The fourth device region 110 includes a diode, which may further be a Zener diode. The diode in the fourth device region 110 includes the fourth patterned first semiconductor layer 122d with the Zener region 510 as a cathode and a portion (e.g., a p-doped portion or region) of the semiconductor substrate 102 as an anode (e.g., electrically contacted through metal contacts 820). The first dielectric layer 702 is conformal to the fourth patterned first semiconductor layer 122d. For example, the first dielectric layer 702 is on sidewalls and upper surfaces of the fourth patterned first semiconductor layer 122d. The first dielectric layer 702 is further on sidewalls and bottom surfaces that define the recesses 602 in the semiconductor substrate 102 that are at a periphery of the diode.

The fifth device region 112 includes a capacitor. The capacitor in the fifth device region 112 includes the second patterned third semiconductor layer 126b as a bottom plate and the metal plate 856 as a top plate. Any semiconductor layer 122e, 124d, 126b in the fifth device mesa 204 may form the bottom plate with any overlying semiconductor layer(s) removed. Using a different semiconductor layer of the fifth device mesa 204 may tune a combined thickness of the dielectric layers 702, 704 between the bottom plate and top plate to implement a target capacitance of the capacitor. The first dielectric layer 702 is conformal to the fifth patterned first semiconductor layer 122e, fourth patterned second semiconductor layer 124d, and second patterned third semiconductor layer 126b. For example, the first dielectric layer 702 is on an upper surface of the second patterned third semiconductor layer 126b and sidewalls of the fifth patterned first semiconductor layer 122e, fourth patterned second semiconductor layer 124d, and second patterned third semiconductor layer 126b. The first dielectric layer 702 is further on sidewalls and bottom surfaces that define the recesses 602 in the semiconductor substrate 102 that are at a periphery of the capacitor.

An IC may include any of the devices as illustrated in the device regions 104-112 in FIG. 8. An IC may include multiple of any of the devices and/or may omit any of the devices. The devices are illustrated to show how the various devices may be formed in a method of manufacturing an IC. Any component or device may be repeated to form multiple devices, and any processing for any device may be omitted to omit such device in an IC.

The semiconductor processing described above may reduce the number of photolithography processes used to form devices in an IC (e.g., that includes one or more BJTs). In situ doping semiconductor layers during epitaxial growth, as described above, may obviate photolithography processes used to form photoresist masks for diffusion layer implantations. By avoiding those photolithography processes, bottlenecks in semiconductor processing caused by photolithography may be avoided, and time to manufacture an IC may be reduced. Additionally, avoiding these diffusion layer implantations may also avoid thermal diffusion processes, which may further reduce manufacturing time. Avoiding the photolithography processes may also reduce processing costs. In situ doped semiconductor layers may have improved dopant uniformity and improved junction control for p-n junctions of a device.

Further, the formation of the dielectric layer(s) in the recesses in the semiconductor substrate and conformally on devices may permit a unified isolation strategy for an IC. Oxide isolation (e.g., as opposed to junction isolation) may be implemented in the semiconductor substrate, which may improve isolation of devices. The semiconductor layers that are implemented for a given device (e.g., BJT) may be nearly fully or fully used for that device such that reduced or no paths for stray electron flow may exist, which may result in improved leakage performance of the device.

Although various examples have been described in detail, it should be understood that various changes, substitutions, and alterations may be made therein without departing from the scope of the disclosure.

What is claimed is:

1. A method of manufacturing an integrated circuit (IC), the method comprising:
forming a semiconductor layer stack over a semiconductor substrate, the semiconductor layer stack including a first semiconductor layer over the semiconductor substrate, a second semiconductor layer over the first semiconductor layer, and a third semiconductor layer over the second semiconductor layer, the first semiconductor layer and the third semiconductor layer having a same conductivity type, the second semiconductor layer having a conductivity type opposite from the conductivity type of the first semiconductor layer and the third semiconductor layer;
patterning the semiconductor layer stack into a first mesa in a first region, the first mesa forming a first emitter of a first bipolar junction transistor (BJT); and
patterning the semiconductor layer stack into a second mesa in the first region, the second mesa extending laterally from the first mesa, the first mesa being over the second mesa, the second mesa forming a first base of the first BJT.

2. The method of claim 1, further comprising:
forming a recess through the first semiconductor layer and into the semiconductor substrate; and
forming a conformal dielectric layer on the first mesa and the second mesa and in the recess.

3. The method of claim 1, wherein patterning the semiconductor layer stack into the second mesa further patterns the semiconductor layer stack into a third mesa in a second region, the third mesa forming a second emitter of a second BJT.

4. The method of claim 3, further comprising forming a recess through the first semiconductor layer and into the semiconductor substrate, the recess being between the first BJT and the second BJT.

5. The method of claim 3, wherein:
the first BJT includes:
the first emitter including the third semiconductor layer in the first mesa;
the first base including the second semiconductor layer in the second mesa; and
a first collector including a first portion of the first semiconductor layer under the second mesa; and
the second BJT includes:
the second emitter including the second semiconductor layer in the third mesa;
a second base including a second portion of the first semiconductor layer under the second mesa; and
a second collector including a portion of the semiconductor substrate under the second portion of the first semiconductor layer.

6. The method of claim 1, wherein the conductivity type of the first semiconductor layer and the third semiconductor layer is n-type doped, and the conductivity type of the second semiconductor layer is p-type doped.

7. The method of claim 1, wherein patterning the semiconductor layer stack into the first mesa and the second mesa in the first region removes the third semiconductor layer and the second semiconductor layer from a second region thereby forming an anode and a cathode of a diode in the second region, the anode including a portion of the first semiconductor layer, the cathode including a portion of the semiconductor substrate.

8. The method of claim 1, further comprising:
implanting a collector region and an emitter region in the semiconductor layer stack in a second region, wherein patterning the semiconductor layer stack into the second mesa in the first region further patterns the semiconductor layer stack into a third mesa in the second region, the third mesa including the collector region and the emitter region; and
implanting a base region in the third mesa and laterally between the collector region and the emitter region, a second BJT including the collector region, the base region, and the emitter region.

9. A method of manufacturing an integrated circuit (IC), the method comprising:
forming a first epitaxial layer over a semiconductor substrate, the first epitaxial layer having a first conductivity type;
forming a second epitaxial layer over the first epitaxial layer, the second epitaxial layer having a second conductivity type opposite from the first conductivity type;
forming a third epitaxial layer over the second epitaxial layer, the third epitaxial layer having the first conductivity type;
etching the third epitaxial layer to form a first emitter layer of a first bipolar junction transistor (BJT) in a first region; and
etching the second epitaxial layer to form a first base layer of the first BJT in the first region, the first emitter layer being over the first base layer, the first base layer extending laterally from the first emitter layer.

10. The method of claim 9, further comprising:
forming a recess through the first epitaxial layer and into the semiconductor substrate; and
forming a conformal dielectric layer on the first emitter layer and the first base layer and in the recess.

11. The method of claim 9, wherein etching the second epitaxial layer further forms a second emitter layer of a second BJT in a second region.

12. The method of claim 11, further comprising forming a recess through the first epitaxial layer and into the semiconductor substrate, the recess being between the first BJT and the second BJT.

13. The method of claim 11, wherein:
the first BJT further includes a first collector layer formed from the first epitaxial layer in the first region; and
the second BJT includes:
a second base layer formed from the first epitaxial layer in the second region; and
a second collector layer including a portion of the semiconductor substrate under the second base layer.

14. The method of claim 9, wherein the first conductivity type is n-type doped, and the second conductivity type is p-type doped.

15. The method of claim 9, wherein etching the third epitaxial layer and the second epitaxial layer in the first region removes the third epitaxial layer and the second epitaxial layer from a second region, a diode being formed in the second region, the diode including an anode and a cathode, the anode including a portion of the first epitaxial layer, the cathode including a portion of the semiconductor substrate.

16. The method of claim 9, further comprising:
implanting a collector region and an emitter region in the second epitaxial layer in a second region, wherein etching the third epitaxial layer further removes the third epitaxial layer from the second region; and
implanting a base region in the second epitaxial layer and the first epitaxial layer and laterally between the collector region and the emitter region, a second BJT including the collector region, the base region, and the emitter region.

17. An integrated circuit (IC) comprising:
a semiconductor substrate;
a bipolar junction transistor (BJT) including a semiconductor layer stack over the semiconductor substrate, the semiconductor layer stack including:
a base semiconductor layer over the semiconductor substrate; and
an emitter semiconductor layer over the base semiconductor layer, the base semiconductor layer extending laterally from the emitter semiconductor layer; and
a conformal dielectric layer on the semiconductor layer stack and in a recess in the semiconductor substrate.

18. The IC of claim 17, wherein the semiconductor layer stack further includes a collector semiconductor layer over the semiconductor substrate, the base semiconductor layer being over the collector semiconductor layer, wherein:
the emitter semiconductor layer is n-type doped;
the base semiconductor layer is p-type doped; and
the collector semiconductor layer is n-type doped.

19. The IC of claim 17, wherein:
the BJT includes a p-doped collector region in the semiconductor substrate under the semiconductor layer stack;
the emitter semiconductor layer is p-type doped; and
the base semiconductor layer is n-type doped.

20. A method of manufacturing an integrated circuit (IC), the method comprising:
forming a bipolar junction transistor (BJT), forming the BJT including forming a semiconductor layer stack over a semiconductor substrate, forming the semiconductor layer stack including:
forming a base semiconductor layer over the semiconductor substrate; and
forming an emitter semiconductor layer over the base semiconductor layer, the base semiconductor layer extending laterally from the emitter semiconductor layer; and
forming a conformal dielectric layer on the semiconductor layer stack and in a recess in the semiconductor substrate.
